(19) United States
(12) Patent Application Publication
(10) Pub. No.: US 2025/0194176 A1
(43) Pub. Date: Jun. 12, 2025

(54) Transistor and Method for Manufacturing Same

(71) Applicant: Microchip Technology Incorporated, Chandler, AZ (US)

(72) Inventors: Shesh Mani Pandey, Gilbert, AZ (US); Randy L. Yach, Phoenix, AZ (US); Bruce Odekirk, Portland, OR (US)

(73) Assignee: Microchip Technology Incorporated, Chandler, AZ (US)

(21) Appl. No.: 18/738,371

(22) Filed: Jun. 10, 2024

Related U.S. Application Data
(60) Provisional application No. 63/609,200, filed on Dec. 12, 2023.
(60) Provisional application No. 63/607,072, filed on Dec. 6, 2023.

(51) Int. Cl. H01L 29/06; H01L 21/265; H01L 21/266; H01L 29/10; H01L 29/66; H01L 29/78

(52) U.S. Cl. CPC H10D 62/109; H01L 21/26513; H01L 21/266; H10D 30/0297; H10D 30/668; H10D 62/393

(57) ABSTRACT

A transistor comprising a drain layer, a drift layer over the drain layer, a channel layer over the drift layer, and a source layer over the channel layer. A trench formed through the source layer, through the channel layer and into at least partially the drift layer. A gate formed within the trench.

### CROSS-REFERENCE TO RELATED APPLICATION

The present application claims priority to U.S. Provisional Patent Application No. 63/607,072, filed on Dec. 6, 2023, and U.S. Provisional Patent Application No. 63/609,200, filed on Dec. 12, 2023, the contents of which are hereby incorporated by reference in their entirety.

### TECHNICAL FIELD

The present disclosure relates generally to transistors, and more specifically to a transistor that has reduced on resistance per unit area, and a method for manufacturing same.

### SUMMARY

According to an aspect of one or more examples, there is provided a transistor that may include a drain layer, a drift layer over the drain layer, a channel layer over the drift layer, a first source layer over the channel layer, a trench formed through the first source layer, through the channel layer and into at least partially the drift layer, and a gate formed within the trench. The drain layer may comprise a first concentration of a first type dopant. The drift layer may comprise a second concentration of the first type dopant. The channel layer may comprise a third concentration of a second type dopant. The first source layer may comprise a fourth concentration of the first type dopant. The transistor may comprise a second source layer between the first source layer and the channel layer, wherein the second source layer may comprise a fifth concentration of the first type dopant. The transistor may comprise a shield layer within the drift layer and adjacent to the gate, wherein the shield layer may comprise a sixth concentration of the second type dopant. The transistor may comprise a drift implant layer formed within the drift layer and adjacent to the shield layer, wherein the drift implant layer may comprise a seventh concentration of the first type dopant. The transistor may comprise a body having a eighth concentration of the second type dopant. The transistor may comprise an insulating layer over the gate within the trench.

According to an aspect of one or more examples, there is provided a method of manufacturing a transistor. The method may include forming a drain layer, forming a drift layer over the drain layer, forming a channel layer over the drift layer, forming a first source layer over the channel layer, forming a trench through the first source layer, through the channel layer and into at least partially the drift layer, and forming a gate within the trench. The drain layer may comprise a first concentration of a first type dopant. The drift layer may comprise a second concentration of the first type dopant. The channel layer may comprise a third concentration of a second type dopant. The first source layer may comprise a fourth concentration of the first type dopant. The method may comprise forming a second source layer between the first source layer and the channel layer, wherein the second source layer may comprise a fifth concentration of the first type dopant. The method may comprise forming a shield layer within the drift layer and adjacent to the gate, wherein the shield layer may comprise a sixth concentration of the second type dopant. The method may comprise forming a drift implant layer within the drift layer and adjacent to the shield layer, wherein the drift implant layer may comprise a seventh concentration of the first type dopant. The method may comprise forming a body having a eighth concentration of the second type dopant. The method may comprise forming an insulating layer over the gate within the trench.

### BRIEF DESCRIPTION OF DRAWINGS

FIG. 1 shows a transistor according to one or more examples.

FIG. 2 shows a transistor with a second source layer according to one or more examples.

FIG. 3 shows a transistor with a second source layer and a shield layer according to one or more examples.

FIG. 4 shows a transistor with a second source layer, a shield layer and a drift implant layer according to one or more examples.

FIGS. 5A through 5H show a method of manufacturing a transistor with a shield layer and a drift implant layer according to one or more examples.

FIGS. 6A through 6H show a method of manufacturing a transistor with a second source layer, a shield layer and a drift implant layer according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Trench metal-oxide-semiconductor field-effect transistors (MOSFETs) have low ON state resistance, and are often used for low and medium voltage applications. However, there is a need for a transistor that has a lower capacitance and an increased drive current.

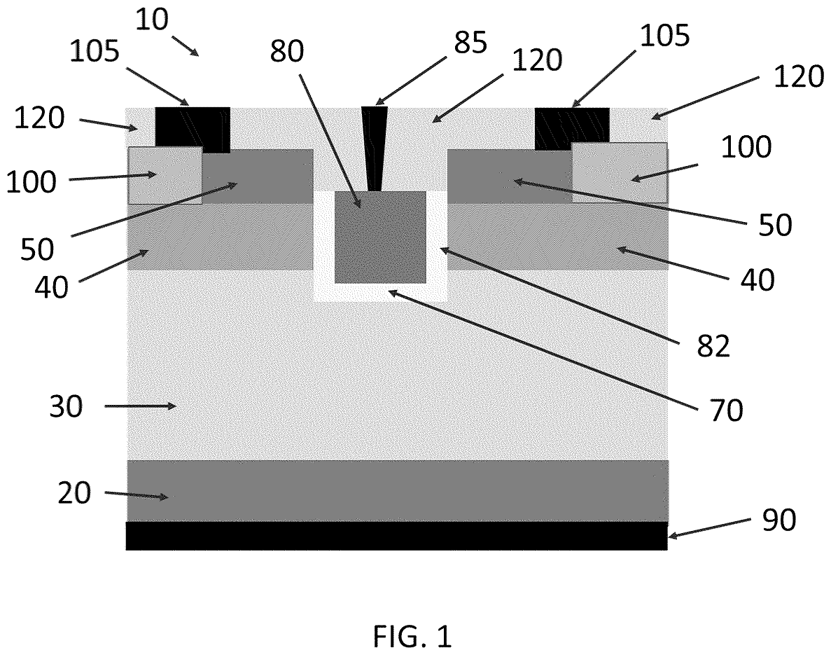

The transistor 10 shown in FIG. 1 may include a drain layer 20, which may have a first concentration of a first type dopant. The transistor 10 of FIG. 1 may include a drift layer 30 formed on the drain layer 20. The drift layer 30 may have a second concentration of the first type dopant. The second concentration may be different from the first concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. The transistor 10 of FIG. 1 may also include a source layer 50 formed over the channel layer 40. The source layer 50 may have a fourth concentration of the first type dopant.

A trench 70 may be formed through the source layer 50, through the channel layer 40 and at least partially into the drift layer 30 using any suitable etching process. A gate oxide layer 82 may be deposited within the trench 70. A gate 80 may be formed by depositing polysilicon within the trench 70 and on the deposited gate oxide layer 82.

The transistor 10 of FIG. 1 may also include one or more bodies 100. As shown in FIG. 1, two bodies 100 may be formed on opposite ends of the source layer 50. The bodies 100 may be implanted in the source layer 50. The bodies 100 may have a fifth concentration of the second type dopant.

The transistor 10 of FIG. 1 may also include at least one gate terminal contact 85 formed on the gate 80, and a drain terminal contact 90 formed on the drain layer 20, wherein the drain terminal contact 90 is formed on an opposing face of drain layer 20 from the drift layer 30. The transistor 10 of FIG. 1 may also include at least one source terminal contact 105 formed adjacent to a respective at least one body 100.

The transistor 10 of FIG. 1 may also include an insulating layer 120 which overlays a top portion of the gate 80 within the trench 70. The insulating layer 120 may also overlay the source layer 50 and may overlay the bodies 100. The insulating layer 120 may comprise polysilicon, silicon dioxide or any other insulator material or a mixture of polysilicon and silicon dioxide or any insulator material.

In the example transistor 10 of FIG. 1, the trench 70 created through the source layer 50, through the channel layer 40 and partially into the drift layer 30 creates a vertical wall in the channel layer 40 which defines the transistor channel by which charge carriers flow from the source layer 50 to the drain terminal 90. The trench 70 may reduce the resistance of the drift layer which may result in a lower on resistance R_{dsoon} per unit area for the transistor 10 which may result in a higher current for the transistor 10.

In the example transistor 10 of FIG. 1, the first type dopant may be an N-type dopant with the second type dopant being a P-type dopant. Alternatively, the first type dopant may be a P-type dopant with the second type dopant being an N-type dopant.

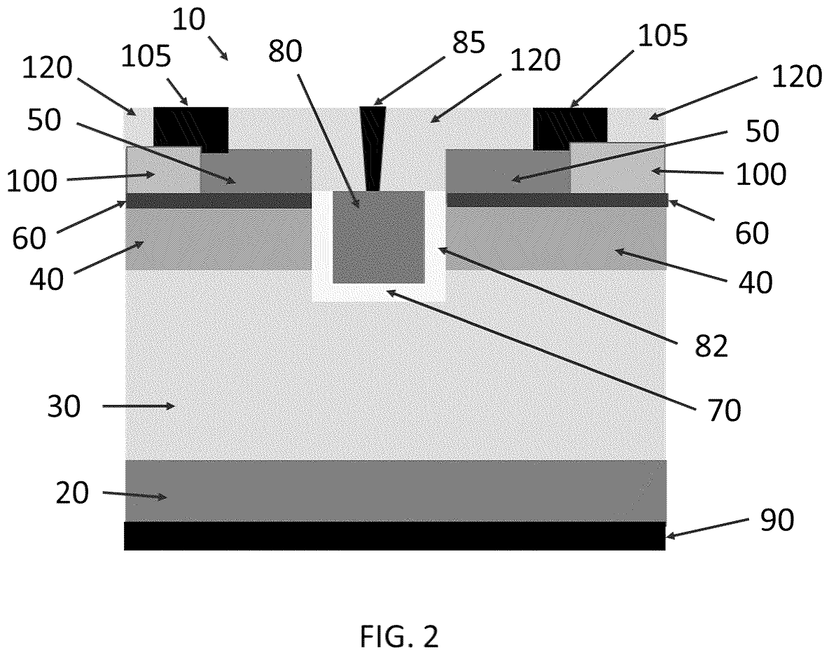

FIG. 2 shows a transistor 10 according to one or more examples. The transistor 10 of FIG. 2 is similar to the transistor 10 of FIG. 1. Like the transistor 10 of FIG. 1, the transistor 10 of FIG. 2 includes a drain layer 20, which may have a first concentration of a first type dopant. The transistor 10 of FIG. 2 may include a drift layer 30 formed on the drain layer 20. The drift layer 30 may have a second concentration of the first type dopant. The first concentration may be different than the second concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. The transistor 10 of FIG. 2 may also include a first source layer 50 formed over the channel layer 40. The first source layer 50 may have a fourth concentration of the first type dopant. The example transistor 10 of FIG. 2 includes a second source layer 60 that is formed between the first source layer 50 and the channel layer 40. The second source layer 60 may comprise a fifth concentration of the first type dopant. The fifth concentration may be different than the fourth concentration. The fifth concentration of the first type dopant in the second source layer 60 may be less than the fourth concentration of the first type dopant in the first source layer 50.

The example transistor 10 of FIG. 2 includes a trench 70 that may be formed through the first source layer 50, through the second source layer 60, through the channel layer 40 and at least partially into the drift layer 30 using any suitable etching process. A gate oxide layer 82 may be deposited within the trench 70. A gate 80 may be formed by depositing polysilicon within the trench 70 and on the deposited gate oxide layer 82.

The transistor 10 of FIG. 2 may also include one or more bodies 100. As shown in FIG. 2, two bodies 100 may be formed on opposite ends of the first source layer 50. The bodies 100 may be implanted in the first source layer 50. The bodies 100 may have a sixth concentration of the second type dopant.

The transistor 10 of FIG. 2 may also include at least one gate terminal contact 85 formed on the gate 80, and a drain terminal contact 90 formed on the drain layer 20, wherein the drain terminal contact 90 is formed on an opposing face of drain layer 20 from the drift layer 30. The transistor 10 of FIG. 2 may also include at least one source terminal contact 105 formed adjacent to a respective at least one body 100.

The transistor 10 of FIG. 2 may also include an insulating layer 120 which overlays a top portion of the gate 80 within the trench 70. The insulating layer 120 may also overlay the first source layer 50 and may overlay the bodies 100. The insulating layer 120 may comprise polysilicon, silicon dioxide or any other insulator material or a mixture of polysilicon and silicon dioxide or any insulator material.

In the example transistor 10 of FIG. 2, the trench 70 created through the first source layer 50, through the second source layer 60, through the channel layer 40 and partially into the drift layer 30 creates a vertical wall in the channel layer 40 which defines the transistor channel by which charge carriers flow from the source layer 50 to the drain terminal 90. The trench 70 may reduce the resistance of the drift layer which may result in a lower on resistance R_{dsoon} per unit area for the transistor 10 which may result in a higher current for the transistor 10.

In the example transistor 10 of FIG. 2, the first type dopant may be an N-type dopant with the second type dopant being a P-type dopant. Alternatively, the first type dopant may be a P-type dopant with the second type dopant being an N-type dopant.

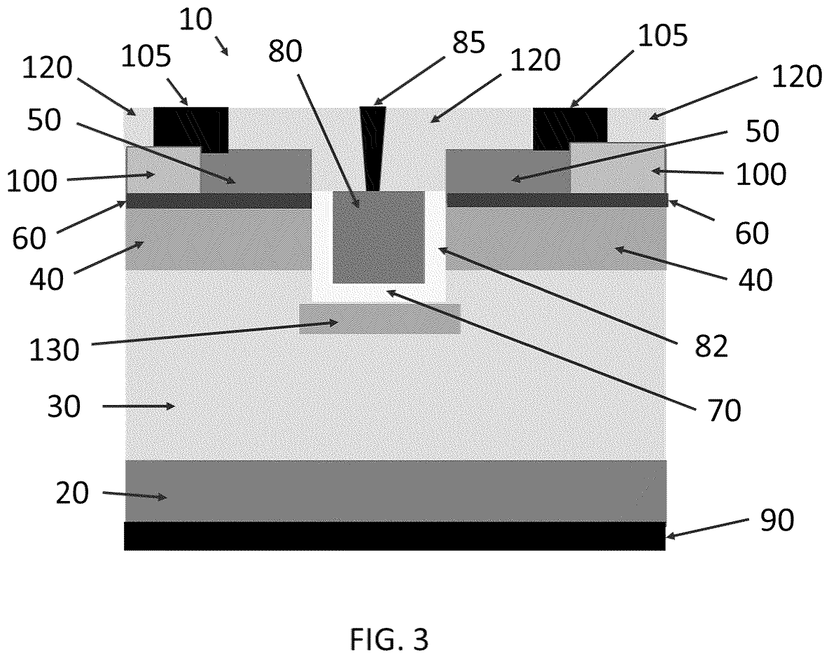

FIG. 3 shows a transistor 10 according to one or more examples. The transistor 10 of FIG. 3 is similar to the transistor 10 of FIGS. 1 and 2. Like the transistor 10 of FIGS. 1 and 2, the transistor 10 of FIG. 3 includes a drain layer 20, which may have a first concentration of a first type dopant. The transistor 10 of FIG. 3 may include a drift layer 30 formed on the drain layer 20. The drift layer 30 may have a second concentration of the first type dopant. The second concentration may be different from the first concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. The transistor 10 of FIG. 3 may also include a first source layer 50 formed over the channel layer 40. The first source layer 50 may have a fourth concentration of the first type dopant. The example transistor 10 of FIG. 3 may include a second source layer 60 that is formed between the first source layer 50 and the channel layer 40. The second source layer 60 may comprise a fifth concentration of the first type dopant. The fifth concentration of the first type dopant in the second source layer 60 may be less than the fourth concentration of the first type dopant in the first source layer 50.

The example transistor 10 of FIG. 3 includes a trench 70 that may be formed through the first source layer 50, through the second source layer 60, through the channel layer 40 and at least partially into the drift layer 30 using any suitable etching process. A gate oxide layer 82 may be deposited within the trench 70. A gate 80 may be formed by depositing polysilicon within the trench 70 and on the deposited gate oxide layer 82.

The example transistor 10 of FIG. 3 may also include a shield layer 130 formed within the drift layer 30 adjacent to the bottom of the trench 70. The shield layer 130 may have a sixth concentration of the second type dopant. The shield layer 130 may be a floating shield layer 130 that is formed within an inner region of the drift layer 30, as shown in FIG. 3. The shield layer 130 may shield the gate oxide 82 within the trench 70 from electric field or voltage that may otherwise damage the gate oxide 82.

The transistor 10 of FIG. 3 may also include one or more bodies 100. As shown in FIG. 3, two bodies 100 may be formed on opposite ends of the first source layer 50. The bodies 100 may be implanted in the first source layer 50. The bodies 100 may have a seventh concentration of the second type dopant.

The transistor 10 of FIG. 3 may also include at least one gate terminal contact 85 formed on the gate 80, and a drain terminal contact 90 formed on the drain layer 20, the drain terminal contact 90 is formed on an opposing face of drain layer 20 from the drift layer 30. The transistor 10 of FIG. 3 may also include at least one source terminal contact 105 formed adjacent to a respective at least one body 100.

The transistor 10 of FIG. 3 may also include an insulating layer 120 which overlays a top portion of the gate 80 within the trench 70. The insulating layer 120 may also overlay the first source layer 50 and may overlay the bodies 100. The insulating layer 120 may comprise polysilicon, silicon dioxide or any other insulator material or a mixture of polysilicon and silicon dioxide or any insulator material.

In the example transistor 10 of FIG. 3, the trench 70 created through the first source layer 50, through the second source layer 60, through the channel layer 40 and partially into the drift layer 30 creates a vertical wall in the channel layer 40 which defines the transistor channel by which charge carriers flow from the source layer 50 to the drain terminal 90. The combination of the shield layer 130 and the trench 70 may reduce the resistance of the drift layer which may result in a lower on resistance R_{dsoon} per unit area for the transistor 10 which may result in a higher current for the transistor 10.

In the example transistor 10 of FIG. 3, the first type dopant may be an N-type dopant with the second type dopant being a P-type dopant. Alternatively, the first type dopant may be a P-type dopant with the second type dopant being an N-type dopant.

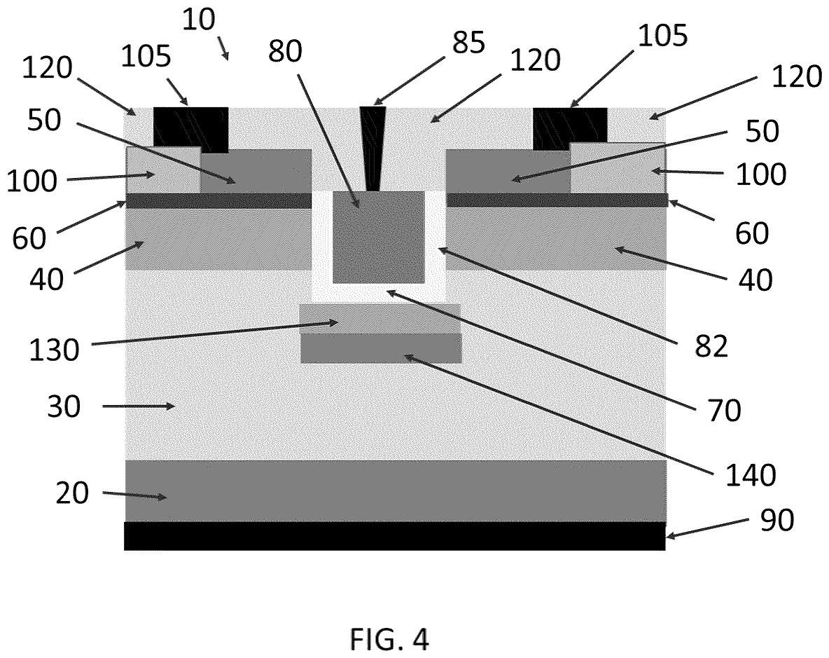

FIG. 4 shows a transistor 10 according to one or more examples. The transistor 10 of FIG. 4 is similar to the transistor 10 of FIGS. 1-3. Like the transistor 10 of FIGS. 1-3, the transistor 10 of FIG. 4 includes a drain layer 20, which may have a first concentration of a first type dopant. The transistor 10 of FIG. 4 may include a drift layer 30 formed on the drain layer 20. The drift layer 30 may have a second concentration of the first type dopant. The second concentration may be different from the first concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. The transistor 10 of FIG. 4 may also include a first source layer 50 formed over the channel layer 40. The first source layer 50 may have a fourth concentration of the first type dopant. The example transistor 10 of FIG. 4 may include a second source layer 60 that is formed between the first source layer 50 and the channel layer 40. The second source layer 60 may comprise a fifth concentration of the first type dopant. The fifth concentration may be different from the fourth concentration. The fifth concentration of the first type dopant in the second source layer 60 may be less than the fourth concentration of the first type dopant in the first source layer 50.

The example transistor 10 of FIG. 4 includes a trench 70 that may be formed through the first source layer 50, through the second source layer 60, through the channel layer 40 and at least partially into the drift layer 30 using any suitable etching process. A gate oxide layer 82 may be deposited within the trench 70. A gate 80 may be formed by depositing polysilicon within the trench 70 and on the deposited gate oxide layer 82.

The example transistor 10 of FIG. 4 may also include a shield layer 130 formed within the drift layer 30 adjacent to the bottom of the trench 70. The shield layer 130 may have a sixth concentration of the second type dopant. The shield layer 130 may be a floating shield layer 130 that is formed within an inner region of the drift layer 30, as shown in FIG. 4. The shield layer 130 may shield the gate oxide 82 within the trench 70 from electric field or voltage that may otherwise damage the gate oxide 82.

The example transistor 10 of FIG. 4 may also include a drift implant layer 140 formed within the drift layer 30 adjacent to the bottom of the shield layer 130. The drift implant layer 140 may comprise a seventh concentration of the first type dopant. The seventh concentration may be different than the second concentration. The seventh concentration of the first type dopant in the drift implant layer 140 may be higher than the second concentration of the first type dopant in the drift layer 30. The drift implant layer 140 may be a floating drift implant layer 140 that is formed within an inner region of the drift layer 30, as shown in FIG. 4. The combination of the shield layer 130, the drift implant layer 140 and the trench 70 may reduce the resistance of the drift layer under the shield layer 130 which may result in a lower on resistance R_{dsoon} per unit area for the transistor 10 which may result in a higher current for the transistor 10.

The transistor 10 of FIG. 4 may also include one or more bodies 100. As shown in FIG. 4, two bodies 100 may be formed on opposite ends of the first source layer 50. The bodies 100 may be implanted in the first source layer 50. The bodies 100 may have an eighth concentration of the second type dopant.

The transistor 10 of FIG. 4 may also include at least one gate terminal contact 85 formed on the gate 80, and a drain terminal contact 90 formed on the drain layer 20, wherein the drain terminal contact 90 is formed on an opposing face of drain layer 20 from the drift layer 30. The transistor 10 of FIG. 4 may also include at least one source terminal contact 105 formed adjacent to a respective at least one body 100.

The transistor 10 of FIG. 4 may also include an insulating layer 120 which overlays a top portion of the gate 80 within the trench 70. The insulating layer 120 may also overlay the first source layer 50 and may overlay the bodies 100. The insulating layer 120 may comprise polysilicon, silicon dioxide or any other insulator material or a mixture of polysilicon and silicon dioxide or any insulator material.

In the example transistor 10 of FIG. 4, the trench 70 created through the first source layer 50, through the second source layer 60, through the channel layer 40 and partially into the drift layer 30 creates a vertical wall in the channel layer 40 which defines the transistor channel by which charge carriers flow from the source layer 50 to the drain terminal 90.

In the example transistor 10 of FIG. 4, the first type dopant may be an N-type dopant with the second type dopant being a P-type dopant. Alternatively, the first type dopant may be a P-type dopant with the second type dopant being an N-type dopant.

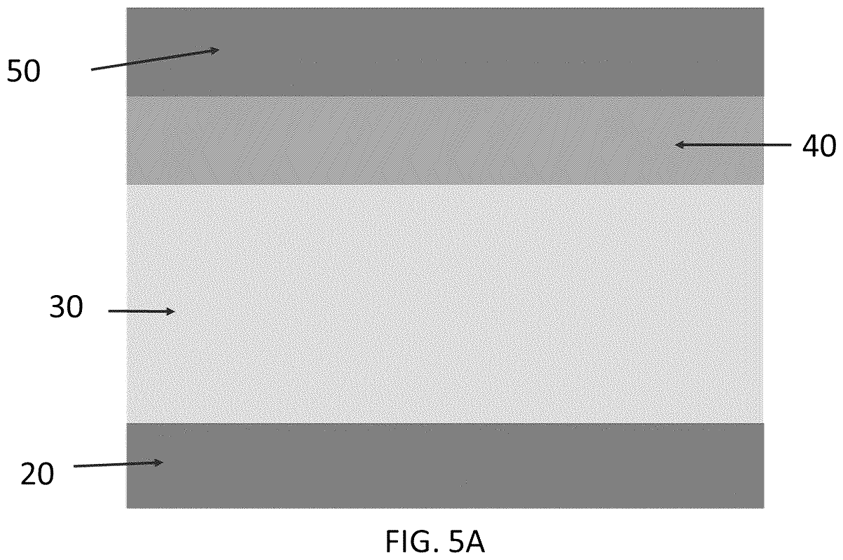

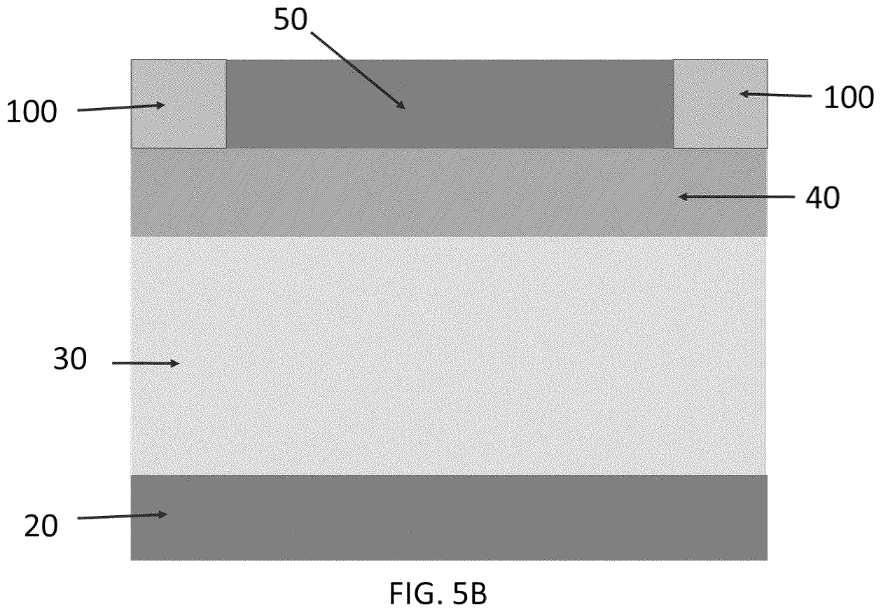

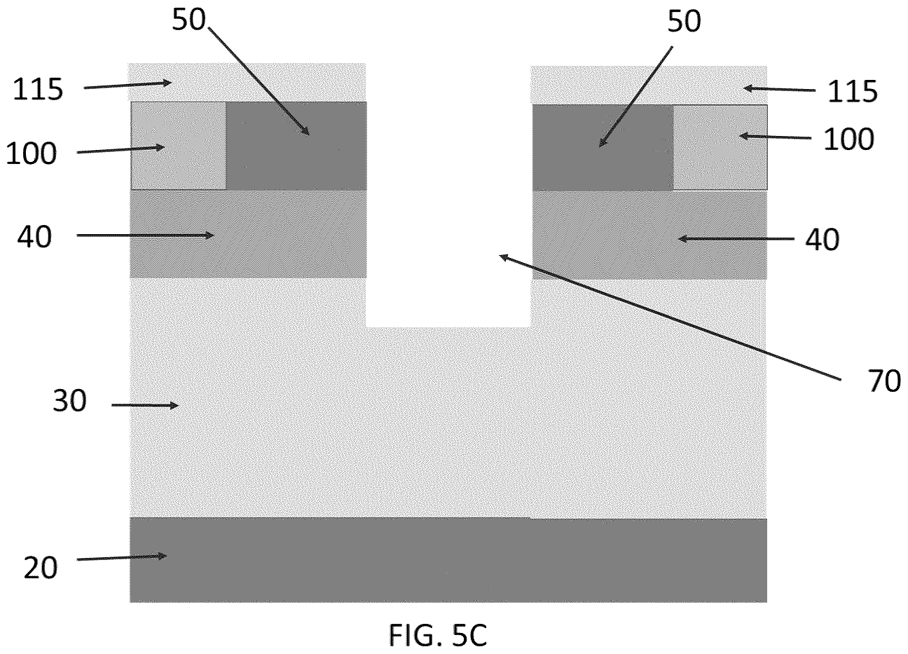

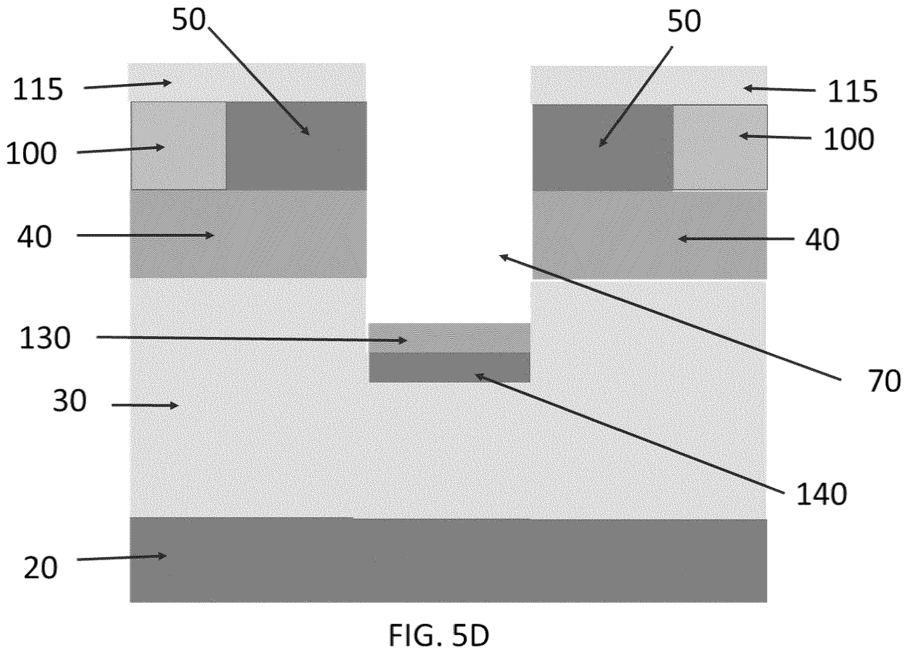

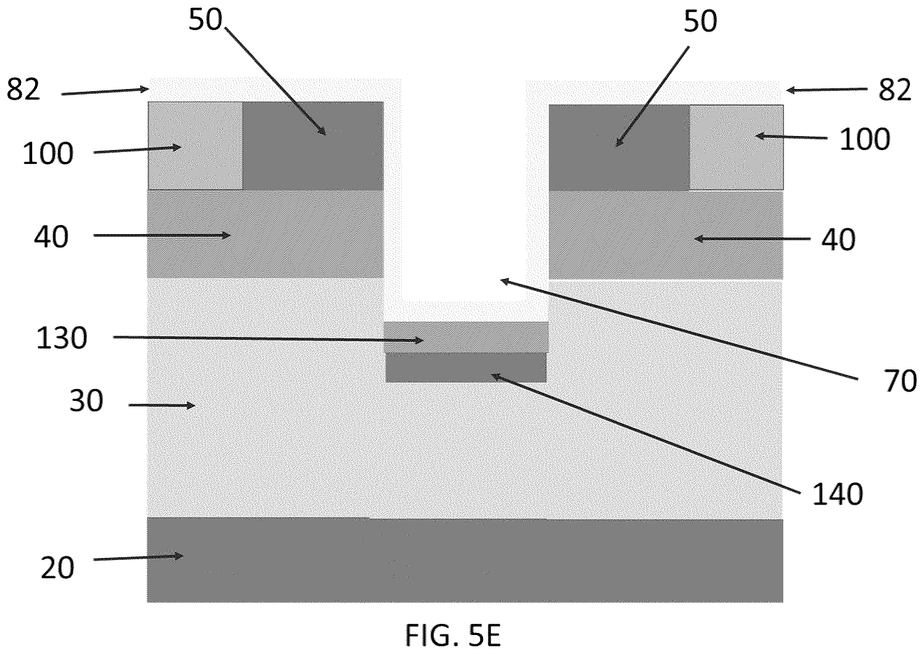

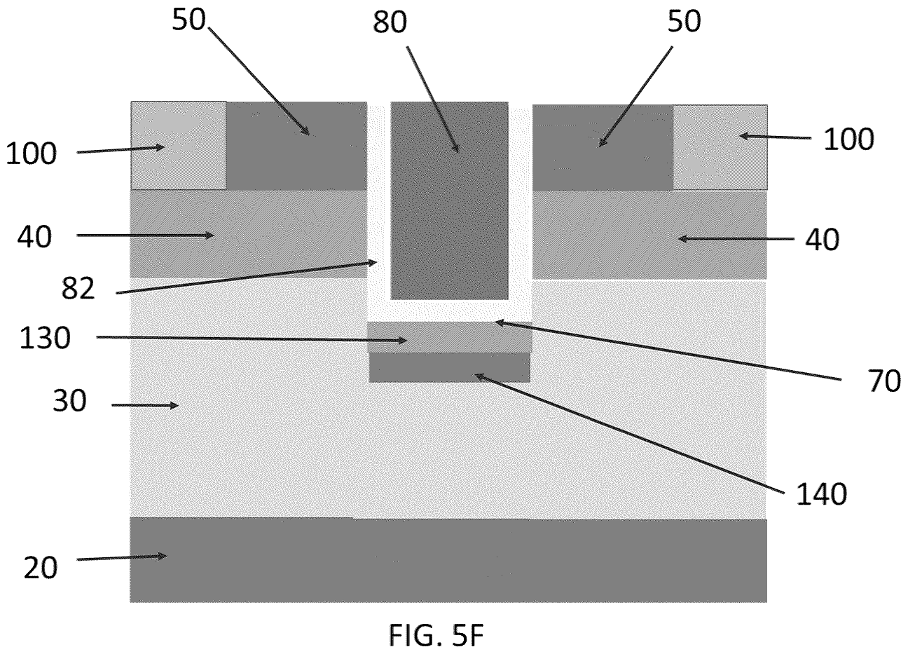

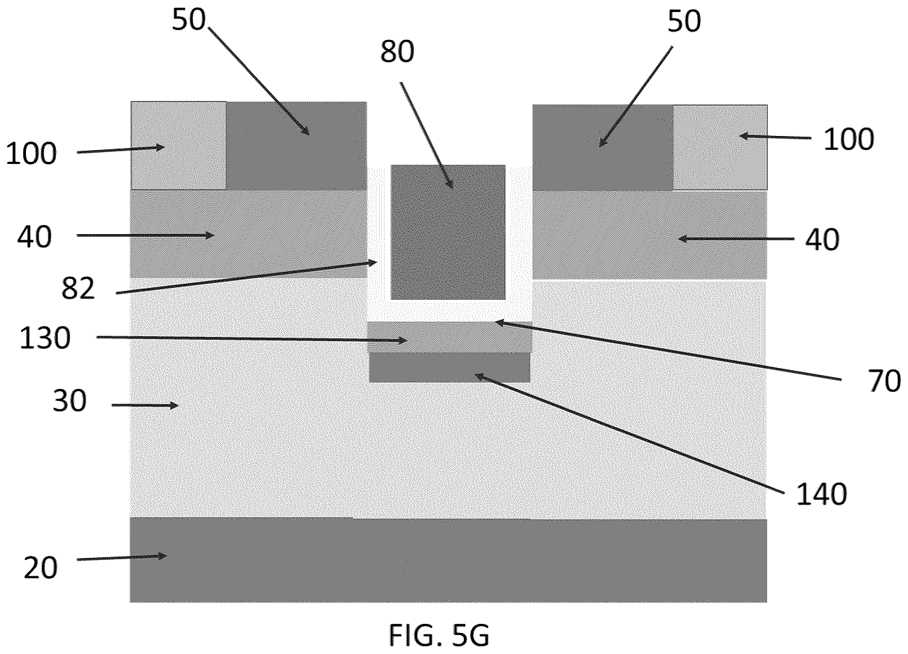

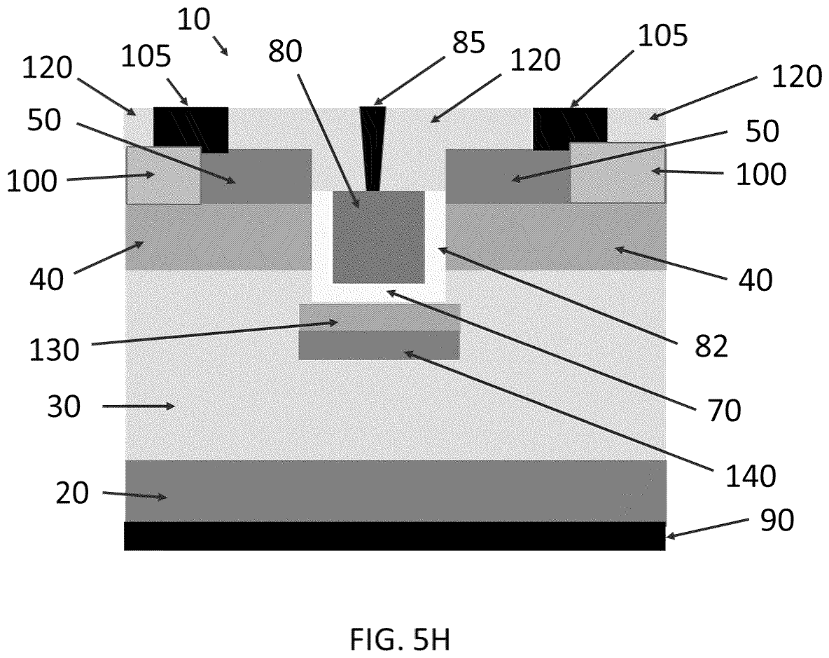

FIGS. 5A through 5H show a method of manufacturing a transistor 10 according to one or more examples. Although the example method shown in FIGS. 5A-5H include steps shown in a particular order, the steps may be performed in a different order, and may include additional steps that are not explicitly shown.

In FIG. 5A, a drain layer 20 may be formed having a first concentration of a first type dopant. A drift layer 30 may be formed on the drain layer 20. The drift layer 30 may have a second concentration of the first type dopant. The first concentration may be different from the second concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. A source layer 50 may be formed over the channel layer 40. The source layer 50 may have a fourth concentration of the first type dopant. At least the source layer 50 and the channel layer 40 may be epitaxially grown.

In FIG. 5B, one or more bodies 100 may be formed in the source layer 50. The one or more bodies 100 may have a fifth concentration of the second type dopant.

In FIG. 5C, a mask 115 may be selectively applied to a top surface of the source layer 50 and the at least one body 100 to protect certain portions of the source layer 50, and leave other portions of the source layer 50 exposed to form the trench 70. A trench 70 may then be formed by etching through the source layer 50, through the channel layer 40, and at least partially into the drift layer 30.

In FIG. 5D, according to one or more examples, the method may also include a step of forming a drift implant layer 140 within the drift layer 30. The drift implant layer 140 may comprise a sixth concentration of the first type dopant. The sixth concentration may be different than the second concentration. The sixth concentration of the first type dopant in the drift implant layer 140 may be higher than the second concentration of the first type dopant in the drift layer 30. As shown in FIG. 5D, the method may also include a step of forming a shield layer 130 within the drift layer 30 adjacent to the bottom of the trench 70 and above the drift implant layer 140. The shield layer 130 may have a seventh concentration of the second type dopant.

In FIG. 5E, the mask is removed, and a gate oxide layer 82 may be formed in the trench 70. The gate oxide layer 82 may also be formed on the source layer 50 and the one or more bodies 100 outside of the trench 70.

In FIG. 5F, the gate oxide layer 82 may be removed from the top surface of the source layer 50 and the one or more bodies 100. A gate 80 may be formed by depositing polysilicon within the trench 70 on the gate oxide layer 82 that was formed in the trench 70.

In FIG. 5G, a portion of the polysilicon of the gate 80 and a portion of the gate oxide layer 82 may be etched from the trench 70.

In FIG. 5H, an oxide layer 120 may be formed on the top surface of the source layer 50 and the one or more bodies 100, and on the top surface of the polysilicon of the gate 80 and the gate oxide 82 within the trench 70. A gate terminal contact 85 may be formed to contact the gate 80 within the trench. One or more source terminal contacts 105 may be formed on the source layer 50 and on respective bodies 100. A drain terminal contact 90 may be formed on the drain layer 20. As shown in FIG. 5H, the combination of the shield layer 130, the drift implant layer 140 and the trench 70 may reduce the resistance of the drift layer under the shield layer 130 which may result in a lower on resistance R_{dsoon} per unit area for the transistor 10 which may result in a higher current for the transistor 10.

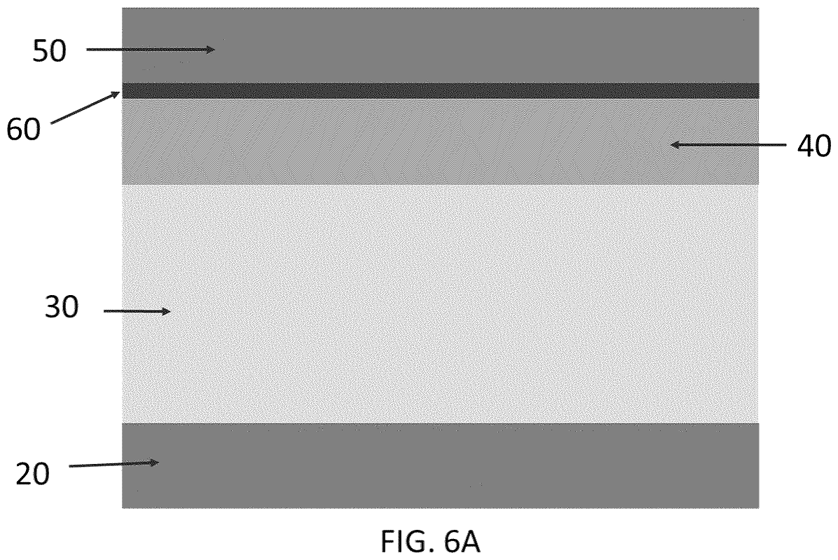

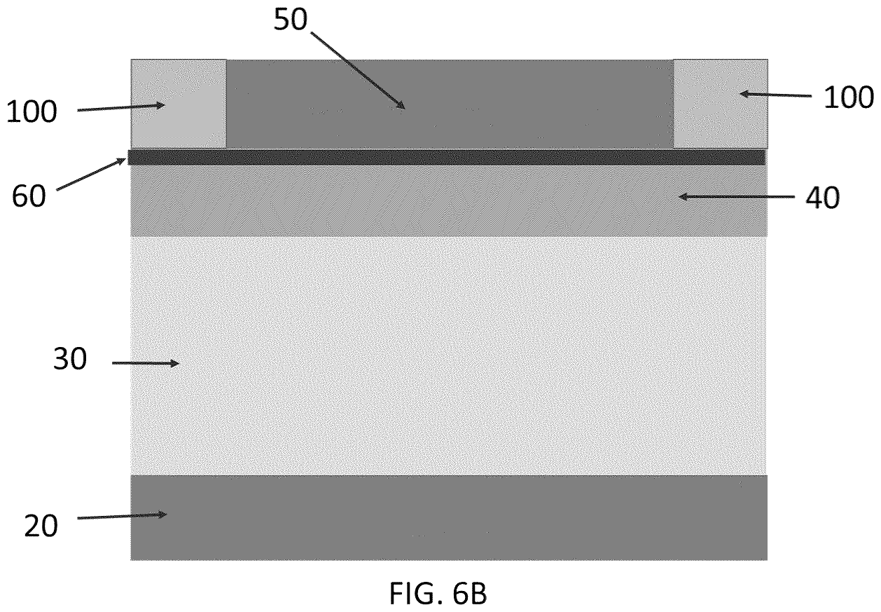

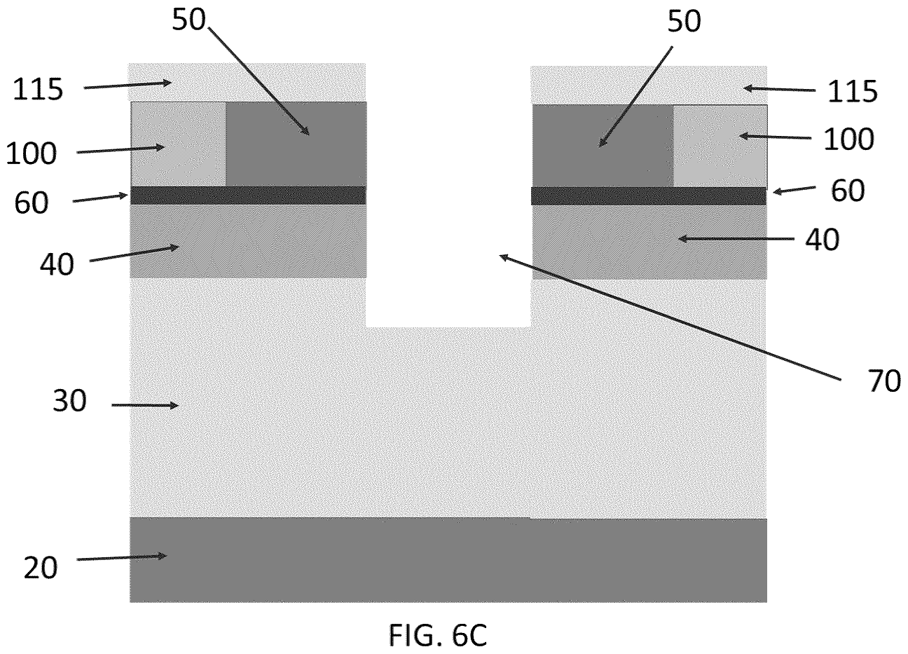

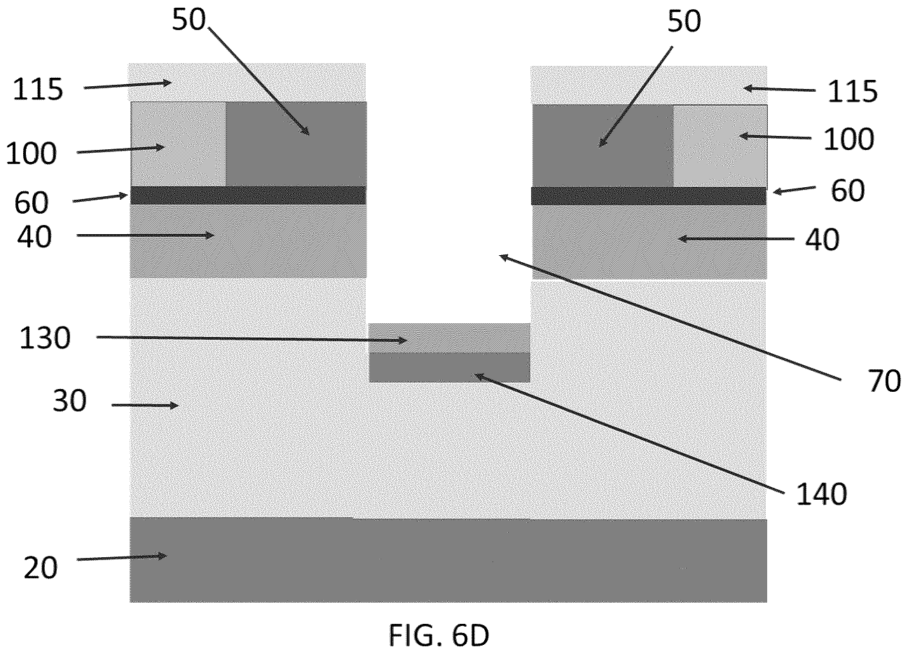

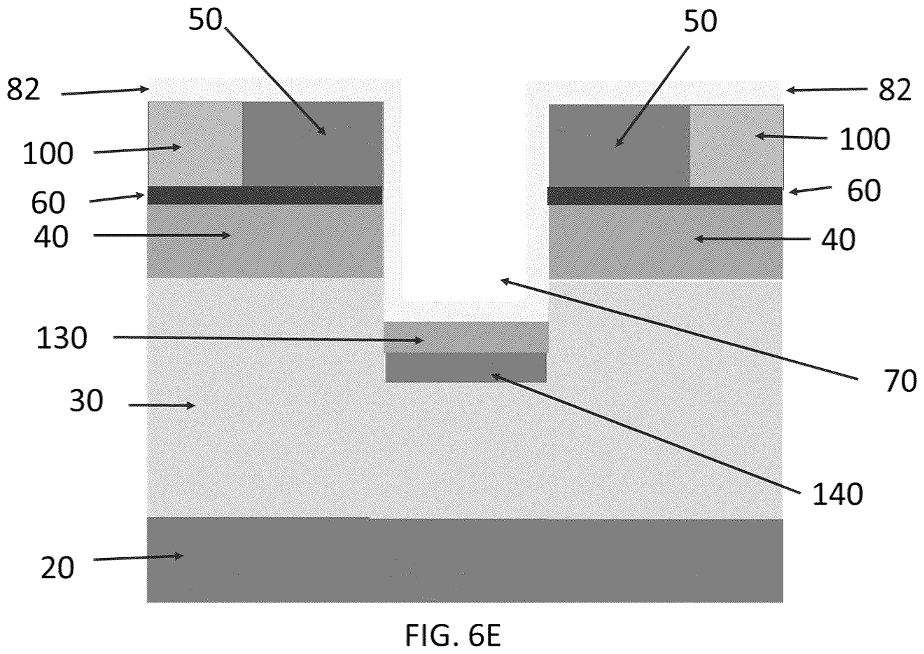

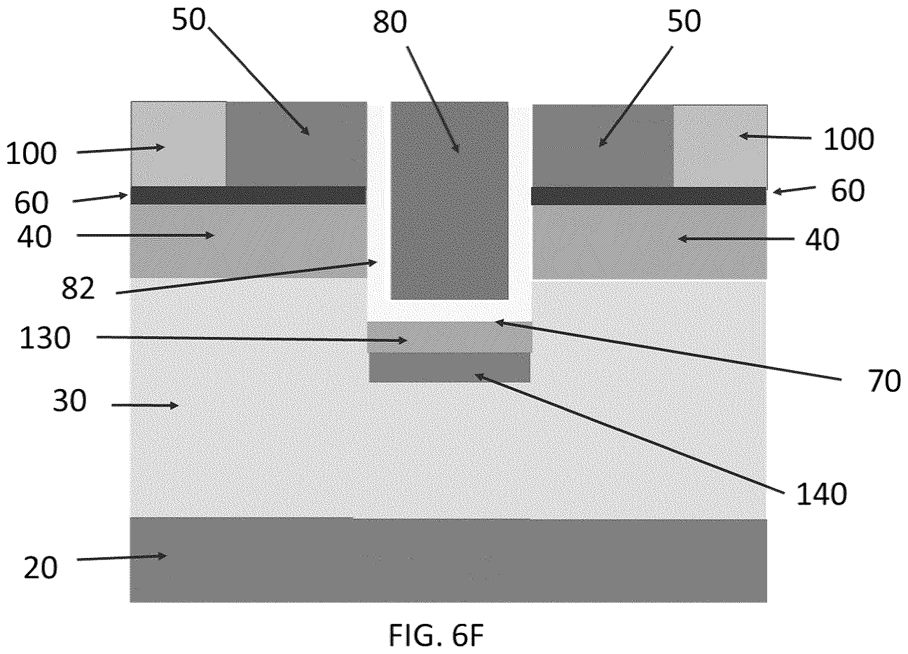

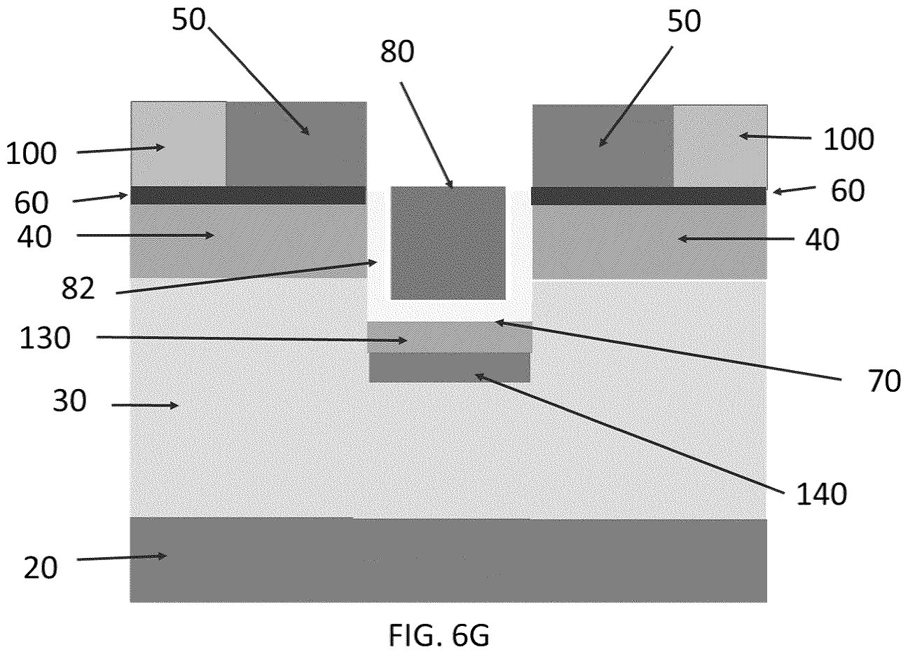

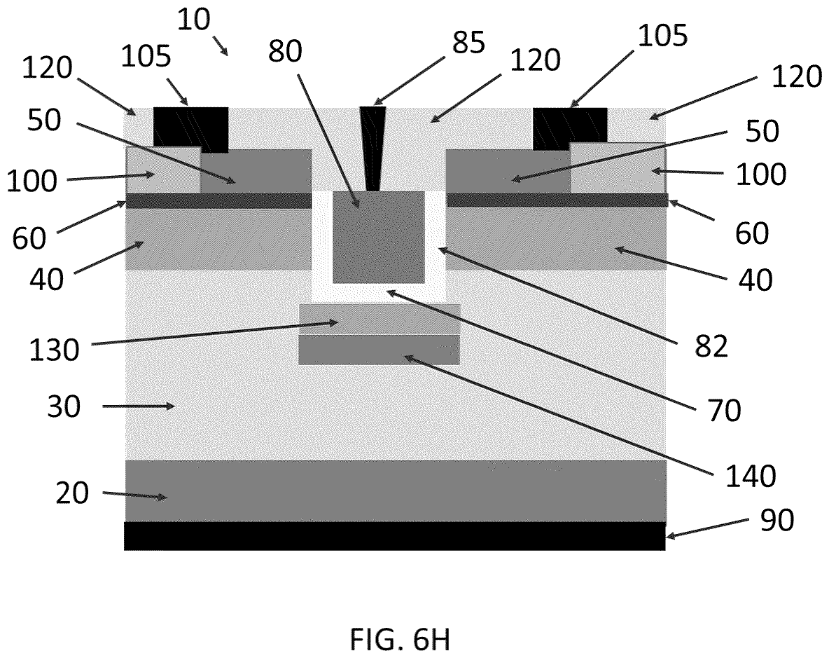

FIGS. 6A through 6H show a method of manufacturing a transistor 10 according to one or more examples. Although the example method shown in FIGS. 6A-6H include steps shown in a particular order, the steps may be performed in a different order, and may include additional steps that are not explicitly shown.

In FIG. 6A, a drain layer 20 may be formed having a first concentration of a first type dopant. A drift layer 30 may be formed on the drain layer 20. The drift layer 30 may have a second concentration of the first type dopant. The second concentration may be different from the first concentration. The first concentration of the first type dopant in the drain layer 20 may be greater than the second concentration of the first type dopant in the drift layer 30. A channel layer 40 may be formed on the drift layer 30. The channel layer 40 may have a third concentration of a second type dopant. A second source layer 60 may be formed on the channel layer 40 before forming the first source layer 50. The first source layer 50 may have a fourth concentration of the first type dopant. The second source layer 60 may comprise a fifth concentration of the first type dopant. The fifth concentration may be different from the fourth concentration. The fifth concentration of the first type dopant in the second source layer 60 may be less than the fourth concentration of the first type dopant in the first source layer 50. The first source layer 50, the second source layer 60 and the channel layer 40 may be epitaxially grown.

In FIG. 6B, one or more bodies 100 may be formed in the first source layer 50. The one or more bodies 100 may have a sixth concentration of the second type dopant.

In FIG. 6C, a mask 115 may be selectively applied to a top surface of the first source layer 50 and the at least one body 100 to protect certain portions of the first source layer 50, and leave other portions of the first source layer 50 exposed to form the trench 70. A trench 70 may then be formed by etching through the first source layer 50, through the second source layer 60, through the channel layer 40, and at least partially into the drift layer 30.

In FIG. 6D, according to one or more examples, the method may also include a step of forming a drift implant layer 140 within the drift layer 30 adjacent to the bottom of the shield layer 130. The drift implant layer 140 may comprise a seventh concentration of the first type dopant. The seventh concentration may be different from the second concentration. The seventh concentration of the first type dopant in the drift implant layer 140 may be higher than the second concentration of the first type dopant in the drift layer 30. As shown in FIG. 6D, the method may also include a step of forming a shield layer 130 within the drift layer 30 adjacent to the bottom of the trench 70 and above the drift implant layer 140. The shield layer 130 may have an eighth concentration of the second type dopant.

In FIG. 6E, the mask is removed, and a gate oxide layer 82 may be formed in the trench 70. The gate oxide layer 82 may also be formed on the first source layer 50 and the one or more bodies 100 outside of the trench 70.

In FIG. 6F, the gate oxide layer 82 may be removed from the top surface of the first source layer 50 and the one or more bodies 100. A gate 80 may be formed by depositing polysilicon within the trench 70 on the gate oxide layer 82 that was formed in the trench 70.

In FIG. 6G, a portion of the polysilicon of the gate 80 and a portion of the gate oxide layer 82 may be etched from the trench 70. According to one or more examples that include the second source layer 60, the polysilicon of the gate 80 and gate oxide layer 82 may be etched so that a top surface of the remaining gate oxide layer 82 and polysilicon 80 corresponds to the interface between the first source layer 50 and the second source layer 60.

In FIG. 6H, an oxide layer 120 may be formed on the top surface of the first source layer 50 and the one or more bodies 100, and on the top surface of the polysilicon of the gate 80 and the gate oxide 82 within the trench 70. A gate terminal contact 85 may be formed to contact the gate 80 within the trench. One or more source terminal contacts 105 may be formed on the first source layer 50 and on respective bodies 100. A drain terminal contact 90 may be formed on the drain layer 20. As shown in FIG. 6H, the combination of the shield layer 130, the drift implant layer 140 and the trench 70 may reduce the resistance of the drift layer under the shield layer 130 which may result in a lower on resistance R_{dsoon} per unit area for the transistor 10 which may result in a higher current for the transistor 10.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a drain layer;
a drift layer over the drain layer;
a channel layer over the drift layer;
a first source layer over the channel layer;
a trench formed through the first source layer, through the channel layer and at least partially into the drift layer; and
a gate formed within the trench.

2. The transistor of claim 1, wherein the drain layer comprises a first concentration of a first type dopant.

3. The transistor of claim 2, wherein the drift layer comprises a second concentration of the first type dopant, the second concentration different from the first concentration.

4. The transistor of claim 3, wherein the channel layer comprises a third concentration of a second type dopant.

5. The transistor of claim 4, wherein the first source layer comprises a fourth concentration of the first type dopant.

6. The transistor of claim 5, comprising a second source layer between the first source layer and the channel layer, wherein the second source layer comprises a fifth concentration of the first type dopant, the fifth concentration different from the fourth concentration, and the trench is formed through the second source layer.

7. The transistor of claim 6, comprising a shield layer within the drift layer and adjacent to the gate, wherein the shield layer comprises a sixth concentration of the second type dopant.

8. The transistor of claim 7, comprising a drift implant layer formed within the drift layer and adjacent to the shield layer, wherein the drift implant layer comprises a seventh concentration of the first type dopant, the seventh concentration different from the second concentration.

9. The transistor of claim 8, comprising a body having an eighth concentration of the second type dopant.

10. The transistor of claim 1, comprising an insulating layer over the gate within the trench.

11. A method of manufacturing a transistor, the method comprising:
forming a drain layer;
forming a drift layer over the drain layer;
forming a channel layer over the drift layer;
forming a first source layer over the channel layer;
forming a trench through the first source layer, through the channel layer and at least partially into the drift layer; and
forming a gate within the trench.

12. The method of claim 11, wherein the drain layer comprises a first concentration of a first type dopant.

13. The method of claim 12, wherein the drift layer comprises a second concentration of the first type dopant, the second concentration different from the first concentration.

14. The method of claim 13, wherein the channel layer comprises a third concentration of a second type dopant.

15. The method of claim 14, wherein the first source layer comprises a fourth concentration of the first type dopant.

16. The method of claim 15, comprises forming a second source layer between the first source layer and the channel layer, wherein the second source layer comprises a fifth concentration of the first type dopant, the fifth concentration different from the fourth concentration, and the trench is formed through the second source layer.

17. The method of claim 16, comprises forming a shield layer within the drift layer and adjacent to the gate, wherein the shield layer comprises a sixth concentration of the second type dopant.

18. The method of claim 17, comprises forming a drift implant layer within the drift layer and adjacent to the shield layer, wherein the drift implant layer comprises a seventh concentration of the first type dopant, the seventh concentration different from the second concentration.

19. The method of claim 18, comprising forming a body having an eighth concentration of the second type dopant.

20. The method of claim 11, comprising forming an insulating layer over the gate within the trench.
